(19) United States
(12) Patent Application Publication
(10) Pub. No.: US 2014/0312384 A1
(43) Pub. Date: Oct. 23, 2014

(54) SEMICONDUCTOR DEVICE

(71) Applicant: KABUSHIKI KAISHA TOSHIBA, Tokyo (JP)

(72) Inventors: Ryo WADA, Kanagawa (JP); Kaori YOSHIOKA, Kanagawa (JP)

(73) Assignee: KABUSHIKI KAISHA TOSHIBA, Tokyo (JP)

(21) Appl. No.: 14/174,057

(22) Filed: Feb. 6, 2014

(30) Foreign Application Priority Data
Apr. 19, 2013 (JP) 2013-088522

(51) Int. Cl. H01L 29/739

(52) U.S. Cl. CPC H01L 29/7394
USPC 257/141

(57) ABSTRACT

A semiconductor device includes a first base layer of a first conductivity type formed on a semiconductor layer, a second base layer of a second conductivity type formed on a first surface of the first base layer, an emitter layer formed on the second base layer, a collector layer of the second conductivity type formed above the first base layer, and a barrier layer of the first conductivity type formed between the first base layer and the second base layer. The barrier layer has a depth from the first surface that is shallower than a depth of the second base layer from the first surface and a dopant concentration that is higher than a dopant concentration of the first base layer. The semiconductor device further includes an insulating film formed on the second base layer and a gate electrode formed on the insulating film.

### CROSS-REFERENCE TO RELATED APPLICATION

This application is based upon and claims the benefit of priority from Japanese Patent Application No. 2013-088522, filed Apr. 19, 2013, the entire contents of which are incorporated herein by reference.

### FIELD

Embodiments described herein relate generally to a semiconductor device.

### BACKGROUND

Insulated gate bipolar transistors (hereinafter referred to as Insulated Gate Bipolar Transistor (IGBT)) are known as a semiconductor device that has the high speed switching performance of a Metal Insulator Semiconductor Field-Effect Transistor (MISFET) and the high power performance of a bipolar transistor. In order to improve the high power performance of the IGBT, an on-resistance has to be reduced. If the on-resistance is reduced, an undesirable drop in the withstand voltage between an emitter and a collector may occur.

### DESCRIPTION OF THE DRAWINGS

FIG. 1 is a schematic cross-sectional view showing one example of the structure of IGBT according to a first embodiment.

FIG. 2A is a graph showing a relationship between the depth from the surface of a semiconductor layer and n type barrier layers and FIG. 2B is a graph showing a relationship between the depth from the surface of the semiconductor layer and an electric field imposed on a p type base layer.

FIG. 3A is a graph showing a relationship between a peak concentration in the n type barrier layers and a voltage between a collector and an emitter, and FIG. 3B is a graph showing a relationship between the peak concentration in the n type barrier layers and a withstand voltage in the IGBT.

FIG. 4 is a schematic cross-sectional view showing one example of the structure of IGBT according to a second embodiment.

FIG. 5 is a schematic cross-sectional view showing one example of the structure of IGBT according to a third embodiment.

FIG. 6 is a schematic cross-sectional view showing one example of the structure of IGBT according to a fourth embodiment.

### DETAILED DESCRIPTION

In general, according to one embodiment, there is provided a semiconductor device capable of reducing on-resistance while suppressing a drop of a withstand voltage between an emitter and a collector.

A semiconductor device according to one embodiment includes a first base layer of a first conductivity type formed on a semiconductor layer, a second base layer of a second conductivity type formed on a first surface of the first base layer, an emitter layer formed on the second base layer, a collector layer of the second conductivity type formed above the first base layer, a barrier layer of the first conductivity type formed between the first base layer and the second base layer, the barrier layer having a depth from the first surface that is shallower than a depth of the second base layer from the first surface and having a dopant concentration that is higher than a dopant concentration of the first base layer, an insulating film formed on the second base layer, and a gate electrode formed on the insulating film.

Hereinafter, embodiments according to the disclosure will be described with reference to the drawings. The embodiments are not intended to limit the scope of the disclosure. In the following embodiments, the semiconductor substrate is shown with a surface on which a semiconductor element is formed. This surface is defined as an upper surface in the vertical direction but, in some cases, it may be different from the vertical direction that is defined by gravitational acceleration.

### First Embodiment

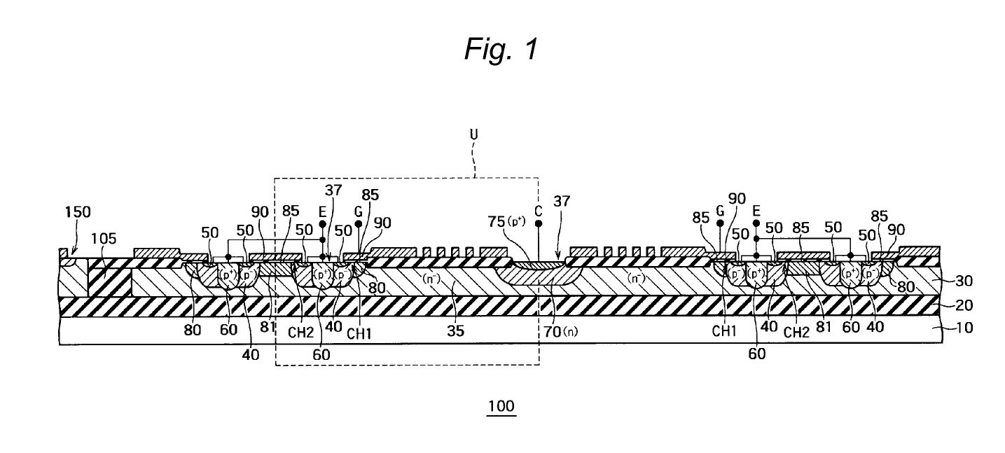

FIG. 1 is a schematic cross-sectional view showing one example of the structure of IGBT 100 according to a first embodiment. The IGBT 100 is formed on a Silicon On Insulator (SOI) substrate including a supporting substrate 10, a Buried Oxide (BOX) layer 20, and a semiconductor layer 30. The supporting substrate 10 and the semiconductor layer 30 are formed by using, for example, single crystal silicon. The BOX layer 20 is formed by using, for example, a silicon oxide film.

The IGBT 100 includes an n type base layer 35 as a first base layer, a p type base layer 40 as a second base layer, an n type emitter layer 50, a p type contact layer 60, an n type buffer layer 70, a p type collector layer 75, n type barrier layers 80 and 81, a gate insulating film 85, and a gate electrode 90.

The n type base layer 35 is a diffusion layer including n type dopants (for example, phosphor or arsenic) and formed in the semiconductor layer 30. The whole semiconductor layer 30 may work as the n type base layer 35. The p type base layer 40 is a diffusion layer including p type dopants (for example, boron) and formed on a first surface 37 of the n type base layer 35.

The n type emitter layer 50 and the p type contact layer 60 are formed in the p type base layer 40. The n type emitter layer 50 is a diffusion layer including a higher concentration of n type dopants than the n type base layer 35 and connected to an emitter electrode E in the IGBT 100. The p type contact layer 60 is a diffusion layer including a higher concentration of p type dopants than the p type base layer 40 and connected to the emitter electrode E together with the emitter layer 50. The p type contact layer 60 is formed deeper than the p type base layer 40 and protruded downward from the bottom surface of the p type base layer 40. In FIG. 1, although the emitter electrode E is shown schematically, it is formed by using a contact plug penetrating an interlayer insulating film and coming into contact with the emitter layer 50 and the p type contact layer 60.

The n type buffer layer 70 is a diffusion layer including a higher concentration of n type dopants than the n type base layer 35 and formed on the first surface 37 of the n type base layer 35. The p type collector layer 75 is formed on the first surface 37 within the n type buffer layer 70 and connected to a collector electrode C in the IGBT 100. Therefore, the IGBT 100 according to the embodiment is a so-called horizontal IGBT. In FIG. 1, although the collector electrode C is schematically shown, it is formed by using a contact plug penetrating the interlayer insulating film and coming into contact with the p type collector layer 75.

The n type barrier layer 80 is formed between the n type base layer 35 and the p type base layer 40 on the surface of the n type base layer 35 (the surface of the semiconductor layer 30) and adjacent to the lateral portion of the p type base layer 40. The n type barrier layer 81 is formed between a plurality of adjacent p type base layers 40 on the surface of the n type base layer 35 (the surface of the semiconductor layer 30) and adjacent to the lateral portions of the p type base layers 40. Namely, the n type barrier layers 80 and 81 are respectively formed adjacently to the both sides of the p type base layer 40. In the depth direction from the first surface 37 of the n type base layer 35, the n type barrier layers 80 and 81 are shallower than the p type base layer 40, the p type contact layer 60, and the n type base layer 35 and deeper than the emitter layer 50. Further, the n type barrier layers 80 and 81 are each a diffusion layer including a higher concentration of n type dopants than the n type base layer 35 and a lower concentration thereof than the emitter layer 50.

The gate insulating film 85 is formed on the p type base layer 40 and the n type barrier layers 80 and 81. Further, the gate electrode 90 is formed on the gate insulating film 85.

Although it is not illustrated, the interlayer insulating film is formed on the gate electrode 90. The contact plug is formed in a way of penetrating through the interlayer insulating film. Further, a wiring layer is formed on the interlayer insulating film or the contact plug.

The p type base layer 40 between the emitter layer 50 and the n type barrier layer 80 becomes a channel region CH1 in the IGBT 100. Therefore, when a voltage is applied to a gate electrode G, the channel region CH1 of the p type base layer 40 is reversed, hence to make the space between the collector electrode C and the emitter electrode E conductive. Further, when a voltage is applied to the collector electrode C, a current flows between the collector electrode C and the emitter electrode E. Here, the on-current from the collector electrode C flows to the emitter electrode E, passing through the p type collector layer 75, the n type buffer layer 70, the n type base layer 35 (drift layer), the n type barrier layer 80, the p type base layer 40 (channel region CH1), and the n type emitter layer 50.

As mentioned above, the dopant concentration of the n type barrier layer 80 is higher than the dopant concentration of the n type base layer 35. Accordingly, the presence of the n type barrier layer 80 between the channel region CH1 of the p type base layer 40 and the n type base layer 35 reduces the on-resistance in the IGBT 100.

On the other hand, the n type barrier layer 80 is formed shallower than the p type base layer 40. Simultaneously, the dopant concentration of the n type barrier layer 80 is lower than that of the emitter layer 50. In this case, a withstand voltage in the IGBT 100 is almost determined in a pn junction between the n type base layer 35 and the p type contact layer 60 whose dopant concentration is higher than the p type base layer 40 or in the pn junction between the n type buffer layer 70 and the p type collector layer 75. Therefore, the n type barrier layer 80 can restrain a drop of the withstand voltage in the IGBT 100 although it is adjacent to the channel region CH1 of the p type base layer 40.

As mentioned above, the IGBT 100 according to the embodiment can reduce the on-resistance while restraining a drop of the withstand voltage. The detailed condition of the dopant concentration in the n type barrier layers 80 and 81 will be described later.

In the embodiment, one collector layer 75 is shared with a plurality of emitter electrodes E formed on the both sides thereof. Namely, one collector layer 75 is shared with a plurality of p type base layers 40 (channel region CH1) formed on the both sides thereof. Therefore, the current of the collector layer 75 flows to the emitter electrodes E through the channel regions CH1 formed on both sides thereof. According to this, the IGBT 100 can flow a large current and achieve a high power performance.

A unit U indicated by a frame of a dotted line in FIG. 1 is a component unit of the IGBT corresponding to one p type base layer 40 (one channel region CH1). The IGBT 100 according to the embodiment is formed by series of the component units shown by the unit U. On the side of the channel CH1 of the p type base layer 40, there is the collector layer 75 and on the other side thereof, there is another p type base layer 40. In the embodiment, the n type barrier layer 81 is formed between the adjacent p type base layers 40. Most of the on-current of the IGBT 100 flows to the channel region CH1. In some cases, however, some of the on-current flows to the n type barrier layer 81 at the opposite side to the channel region CH1 across the p type base layer 40, and the emitter layer 50 passing through the channel region CH2. In this case, the presence of the n type barrier layer 81 between the adjacent p type base layers 40 reduces the on-resistance further.

An element isolation area 105 is provided in order to electrically isolate the IGBT 100 from the other integrated circuits (for example, a motor drive circuit 150). The IGBT 100 according to the embodiment is the horizontal IGBT formed on the SOI substrate. By forming the element isolation area 105, the IGBT 100 can be formed on the same substrate as the other integrated circuits in a mixed way.

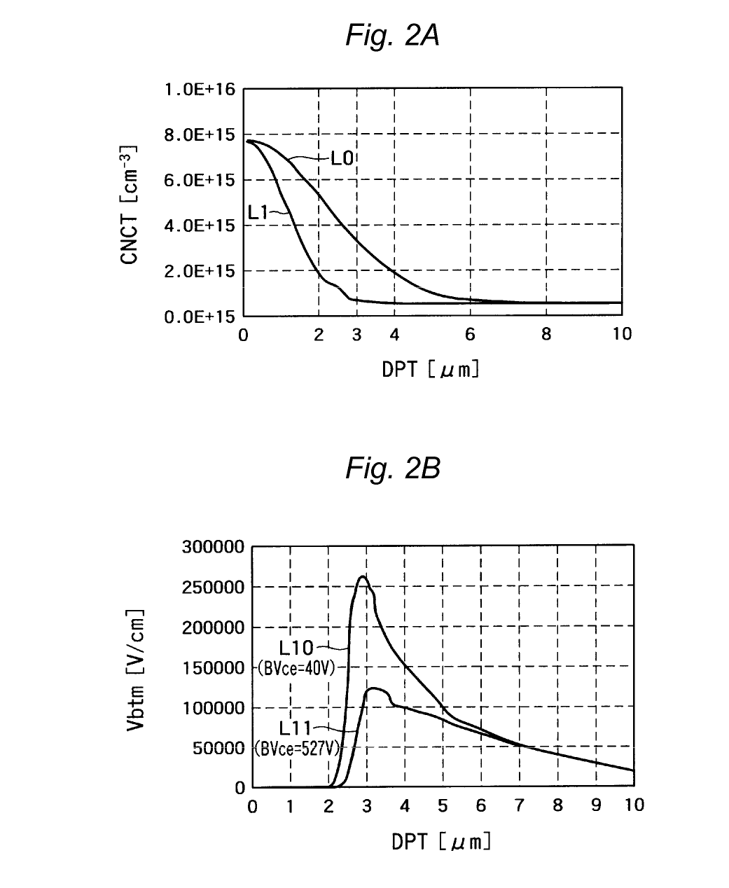

FIG. 2A is a graph showing a relationship between a depth DPT from the surface of the semiconductor layer 30 and a phosphorus concentration CNCT in the n type barrier layers 80 and 81. In the graph of FIG. 2A, the horizontal axis indicates the depth DPT from the surface of the semiconductor layer 30 (the first surface 37 of the n type base layer 35). The vertical axis indicates the phosphorus concentration CNCT in the n type barrier layers 80 and 81.

The phosphorus concentration in the n type barrier layers 80 and 81 according to the embodiment is indicated by a line L1. The n type barrier layer corresponding to a line L0 is formed deeper than the n type barrier layers 80 and 81 according to the embodiment. For example, assuming that the depth of the p type base layer 40 is about 3 micrometers, the depth of the n type barrier layer indicated by the line L0 is deeper than that of the p type base layer 40. In this case, the n type barrier layer reaches the bottom portion of the p type base layer 40, and the n type barrier layer and the bottom portion of the p type base layer 40 form a pn junction. On the contrary, the depth of the n type barrier layers 80 and 81 indicated by the line L1 according to the embodiment is shallower than that of the p type base layer 40. In this case, the n type barrier layers 80 and 81 do not reach the bottom portion of the p type base layer 40. Therefore, although the n type barrier layers 80 and 81 form a pn junction with the lateral side of the p type base layer 40, it does not form the pn junction with the bottom portion of the p type base layer 40.

Further, the maximum dopant concentration (hereinafter, referred to as concentration peak) in the n type barrier layers 80 and 81 is positioned in the vicinity of the first surface of the n type base layer 35. Specifically, the concentration peak in the n type barrier layers 80 and 81 is at the depth within about 0.5 micrometers from the first surface 37 of the n type base layer 35. Here, in FIG. 2A, the maximum dopant concentration in the n type barrier layers 80 and 81 is about 7.7×10¹⁵ cm⁻¹.

FIG. 2B is a graph showing a relationship between the depth DPT from the surface of the semiconductor layer 30 and an electric field Vbtm imposed on the bottom portion of the p type base layer 40 or the bottom portion of the p type contact layer 60. In the graph of FIG. 2B, the horizontal axis indicates the depth DPT from the surface of the semiconductor layer 30 (the first surface 37 of the n type base layer 35). The vertical axis indicates the electric field Vbtm imposed on the bottom portion of the p type base layer 40 or the bottom portion of the p type contact layer 60 when a reverse bias is applied between the collector and the emitter of the IGBT 100 in a nonconductive state. In other words, the electric field Vbtm may be an electric field imposed on the pn junction between the bottom portion of the p type base layer 40 or the bottom portion of the p type contact layer 60 and the n type base layer 35. Hereinafter, a voltage (including reverse bias and forward bias) applied between the collector electrode C and the emitter electrode E is referred to as Vce.

The bottom electric field Vbtm in the embodiment is indicated by a line L11. Namely, when the n type barrier layers 80 and 81 have the concentration distribution indicated by the line L1 in FIG. 2A, the graph of the bottom electric field Vbtm in the p type base layer 40 or the p type contact layer 60 is shown as the line L11. For example, assuming that the depth of the p type base layer 40 is about 3 micrometers, the bottom electric field Vbtm is about 120 kV/cm.

On the other hand, when the n type barrier layer has the concentration distribution indicated by the line L0 in FIG. 2A, the bottom electric field Vbtm is indicated by a line L10. In this case, the n type barrier layer reaches the bottom portion of the p type base layer 40, as mentioned above. Since the n type barrier layer has a higher dopant concentration than the n type base layer, a depletion layer in the bottom portion of the p type base layer 40 expands less than that according to the embodiment. As a result, the bottom electric field Vbtm corresponding to the line L10 becomes higher than the bottom electric field Vbtm according to the embodiment. For example, assuming that the depth of the p type base layer 40 is about 3 micrometers, the bottom electric field Vbtm becomes about 260 kV/cm. When the bottom electric field Vbtm is small like the embodiment, even if the voltage Vce is increased, the electric field imposed on the pn junction between the p type base layer 40 or the p type contact layer 60 and the n type base layer 35 is comparatively small. Therefore, even if the voltage Vce is increased, the pn junction between the p type base layer 40 or the p type contact layer 60 and the n type base layer 35 is unlikely to collapse. According to this, the withstand voltage between the collector and the emitter (hereinafter, referred to as a withstand voltage BVce) in the IGBT 100 indicated by the line L11 according to the embodiment is comparatively higher than the withstand voltage BVce in the IGBT indicated by the line L10. For example, the withstand voltage BVce in the IGBT indicated by the line L10 is about 40 V, while the withstand voltage BVce in the IGBT 100 according to the embodiment is about 527 V.

As mentioned above, the depth of the n type barrier layers 80 and 81 in the IGBT 100 according to the embodiment is shallower than the depth of the p type base layer 40. Therefore, the IGBT 100 according to the embodiment can suppress a drop of the withstand voltage BVce or improve the withstand voltage BVce. Alternatively, the IGBT 100 according to the embodiment can raise the concentration in the n type barrier layers 80 and 81 while maintaining the withstand voltage Vce. By increasing the concentration in the n type barrier layers 80 and 81, the on-resistance in the IGBT 100 can be reduced as described later. In short, the embodiment can reduce the on-resistance in the IGBT 100, while maintaining or improving the withstand voltage in the IGBT 100.

In order to restrain a drop of the withstand voltage in the IGBT 100, it is preferable that the dopant concentration in the n type barrier layers 80 and 81 be not less than the dopant concentration in the n type base layer 35 and not be more than the dopant concentration in the emitter layer 50.

Next, the detailed condition of the dopant concentration in the n type barrier layers 80 and 81 will be described.

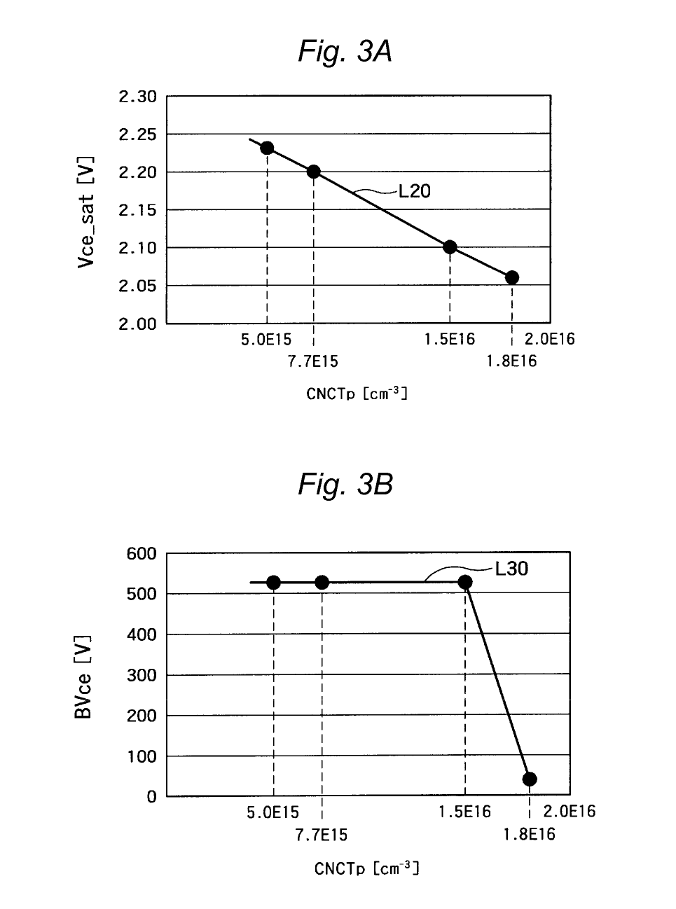

FIG. 3A is a graph showing a relationship between a peak concentration CNCTp in the n type barrier layers 80 and 81 and the voltage Vce between the collector and the emitter. In FIG. 3A, the horizontal axis indicates the peak concentration CNCTp in the n type barrier layers 80 and 81. In FIG. 3A, the vertical axis indicates a voltage Vce_sat imposed between the collector and the emitter when the IGBT 100 is in a conductive state and a constant current flows between the collector and the emitter. For example, the voltage Vce_sat indicates a voltage imposed between the collector and the emitter when a current of 1.0 A flows there, with a voltage of about 15 V applied to the gate electrode G.

As indicated by a line L20 in FIG. 3A, when the peak concentration CNCTp in the n type barrier layers 80 and 81 is increased, the voltage Vce_sat is reduced. For example, when the peak concentration CNCTp is increased from about 5.0×10¹⁵ cm⁻³ to about 1.8×10¹⁶ cm⁻³, the voltage Vce_sat is reduced from about 2.24 V to 2.06 V. This means that the on-resistance in the IGBT 100 gets lower as the peak concentration CNCTp gets higher. Namely, from a viewpoint of the on-resistance, it is preferable that the peak concentration CNCTp in the n type barrier layers 80 and 81 is higher.

FIG. 3B is a graph showing a relationship between the peak concentration CNCTp in the n type barrier layers 80 and 81 and the withstand voltage BVce in the IGBT 100. In FIG. 3B, the horizontal axis indicates the peak concentration CNCTp in the n type barrier layers 80 and 81. In FIG. 3B, the vertical axis indicates the withstand voltage BVce between the collector and the emitter in the IGBT 100. As indicated by a line L30 in FIG. 3B, when the peak concentration CNCTp is increased, the withstand voltage BVce is reduced across the boundary from a certain peak concentration. For example, when the peak concentration CNCTp is about 1.5×10¹⁵ cm⁻³ and less, the withstand voltage BVce is kept at about 520 V and more. However, when the peak concentration CNCTp exceeds about 1.5×10¹⁵ cm⁻³, the withstand voltage BVce abruptly drops. When the peak concentration CNCTp is about 1.8×10¹⁶ cm⁻³, the withstand voltage BVce becomes about 40 V. This means that when the peak concentration CNCTp is increased too much, the IGBT 100 collapses because of the junction withstand voltage between the n type barrier layers 80 and 81 and the p type base layer 40. For example, when the peak concentration CNCTp is increased more than the dopant concentration in the emitter layer 50, the withstand voltage BVce in the IGBT 100 drops. Namely, from the viewpoint of the withstand voltage BVce, it is preferable that the peak concentration CNCTp in the n type barrier layers 80 and 81 is lower to some extent.

As mentioned above, considering the on-resistance and the withstand voltage BVce in the IGBT 100, it is preferable that the peak concentration CNCTp in the n type barrier layers 80 and 81 is in the range of about 5.0×10¹⁵ cm⁻³ to about 1.5×10¹⁶ cm⁻³. According to this, the IGBT 100 according to the embodiment can achieve a low on-resistance, while keeping a high withstand voltage BVce.

According to the embodiment, the dopant concentration in the n type barrier layers 80 and 81 is higher than that in the n type base layer 35. The presence of the n type barrier layers 80 and 81 between the channel region CH1 of the p type base layer 40 and the n type base layer 35 can reduce the on-resistance in the IGBT 100.

Further, the dopant concentration in the n type barrier layers 80 and 81 is lower than the dopant concentration in the emitter layer 50 and the depth of the n type barrier layers 80 and 81 is smaller than the depth of the p type base layer 40. According to this, the n type barrier layers 80 and 81 can restrain a drop of the withstand voltage BVce in the IGBT 100.

Further, it is preferable that the peak concentration in the n type barrier layers 80 and 81 is in the range of about 5.0×10¹⁵ cm⁻³ to about 1.5×10¹⁶ cm⁻³. Accordingly, the IGBT 100 according to the embodiment can reduce the on-resistance while restraining a drop of the withstand voltage.

### Second Embodiment

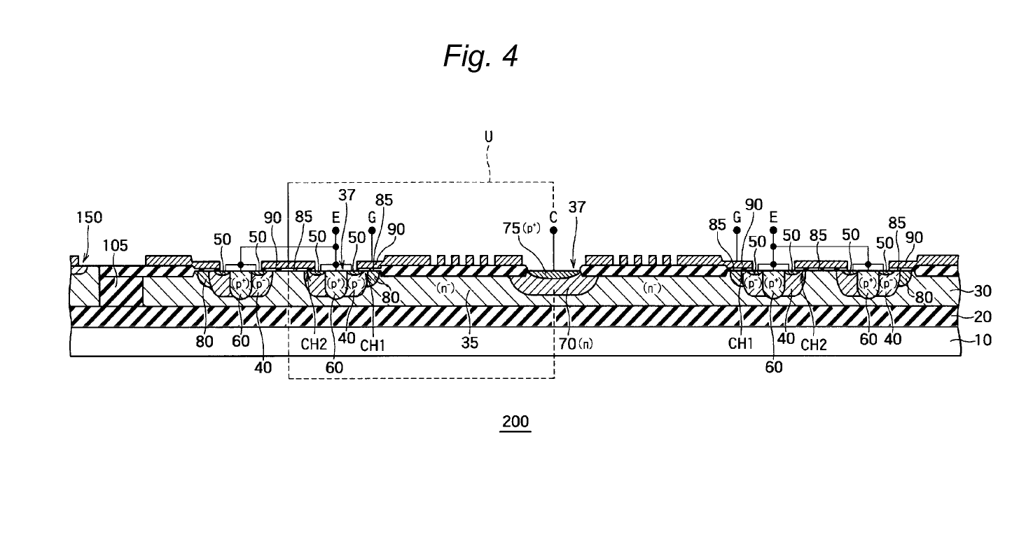

FIG. 4 is a schematic cross-sectional view showing one example of the structure of IGBT 200 according to a second embodiment. The IGBT 200 includes the n type barrier layer 80 between the channel region CH1 of the p type base layer 40 and the n type base layer 35 but does not include the n type barrier layer 81 between the adjacent p type base layers 40. Therefore, the n type barrier layer 80 comes into contact with one lateral side of the p type base layer 40, while the n type base layer 35 comes into contact with the other lateral side of the p type base layer 40. The other structure of the second embodiment is the same as the corresponding structure of the first embodiment.

As mentioned above, most of the on-current of the IGBT 200 flows into the n type barrier layer 80 between the channel region CH1 and the n type base layer 35 and the channel region CH1. Therefore, the IGBT 200 according to the second embodiment can achieve the effect of reducing the on-resistance adequately without the n type barrier layer 81. The IGBT 200 according to the second embodiment, although it does not include the n type barrier layer 81, can achieve the same effect as the first embodiment.

### Third Embodiment

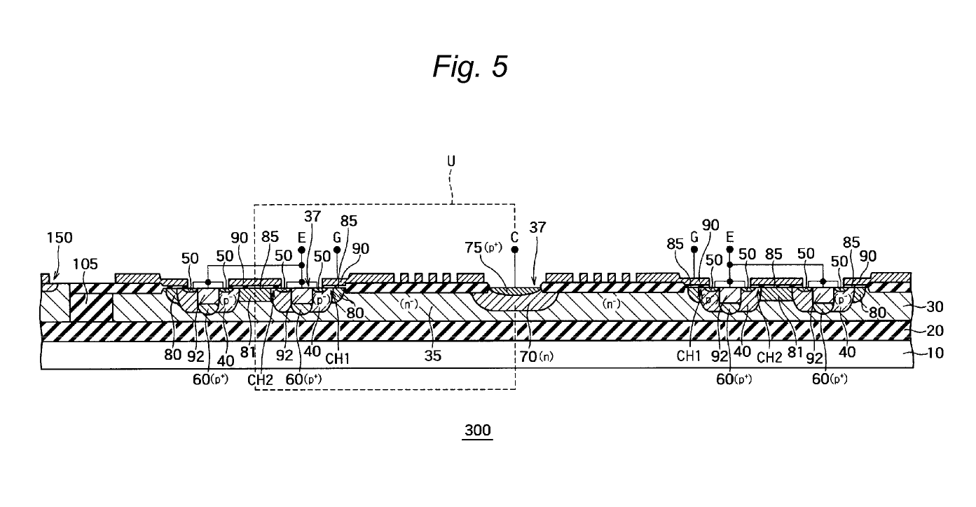

FIG. 5 is a schematic cross-sectional view showing one example of the structure of IGBT 300 according to a third embodiment. The IGBT 300 is different from that of the first embodiment in that the emitter electrode E has a trench contact structure. In the third embodiment, the emitter electrode E connected to the emitter layer 50 and the contact layer 60 contains a plug 92 embedded in a trench TR formed in the p type base layer 40. The plug 92 is formed using a metallic material of a low resistance such as copper, aluminum, and tungsten. By embedding the plug 92 in the trench TR, the IGBT 300 can reduce a contact resistance in the emitter. By reducing the contact resistance in the emitter, the on-resistance can be reduced further. The other structure of the IGBT 300 according to the third embodiment is the same as the corresponding structure of that according to the first embodiment. The IGBT 300 according to the third embodiment has the same effect as the IGBT according to the first embodiment.

### Fourth Embodiment

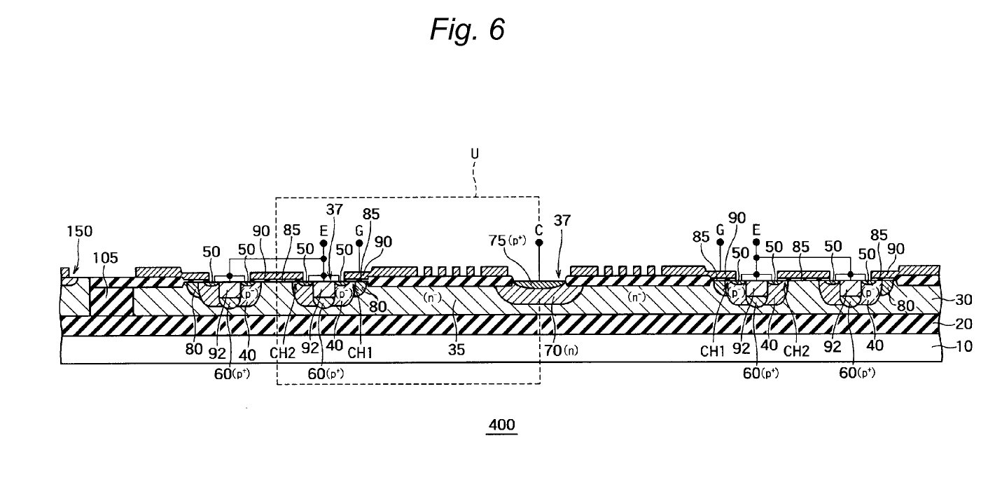

FIG. 6 is a schematic cross-sectional view showing one example of the structure of IGBT 400 according to a fourth embodiment. The IGBT 400 is different from that of the second embodiment in that the emitter electrode E has a trench contact structure. In the fourth embodiment, the emitter electrode E contains the plug 92 embedded in the trench TR formed in the p type base layer 40. The plug 92 is formed using a metallic material of a low resistance such as copper, aluminum, and tungsten. By embedding the plug 92 in the trench TR, the IGBT 400 can reduce a contact resistance in the emitter. By reducing the contact resistance in the emitter, the on-resistance can be reduced further. The other structure of the IGBT 400 according to the fourth embodiment is the same as the corresponding structure of the IGBT according to the second embodiment. The IGBT 400 according to the fourth embodiment has the same effect as the IGBT according to the second embodiment.

In the above embodiments, the IGBTs 100 to 400 are the horizontal IGBT formed on the SOI substrate. As mentioned above, the horizontal IGBT can be formed on the same substrate as other integrated circuits. For example, the IGBTs 100 to 400 can be formed on the same SOI substrate as the motor drive circuit 150 which receives a power supply from the IGBTs 100 to 400. Namely, the IGBTs 100 to 400 can be integrated on the same chip as the motor drive circuit 150.

The n type barrier layers 80 and 81 are formed in the lateral side of the p type base layer 40 adjacently to the channel region CH. According to this, the n type barrier layers 80 and 81 can reduce the on-resistance effectively on the horizontal IGBT. Alternatively, the n type barrier layers 80 and 81 may be applied to a vertical IGBT. Even in this case, the on-resistance can be reduced to some degree.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first base layer of a first conductivity type formed on a semiconductor layer;
a second base layer of a second conductivity type formed on a first surface of the first base layer;
an emitter layer formed on the second base layer;
a collector layer of the second conductivity type formed above the first base layer;
a barrier layer of the first conductivity type, formed between the first base layer and the second base layer, the barrier layer having a depth from the first surface that is shallower than a depth of the second base layer from the first surface and having a dopant concentration that is higher than a dopant concentration of the first base layer;
an insulating film formed on the second base layer; and
a gate electrode formed on the insulating film.

2. The semiconductor device according to claim 1, wherein
the dopant concentration of the barrier layer is lower than a dopant concentration of the emitter layer.

3. The semiconductor device according to claim 1, further comprising:
a buffer layer of the first conductivity type formed on the first base layer,
wherein the collector layer is formed on the buffer layer.

4. The semiconductor device according to claim 1, further comprising:
a contact layer of the second conductivity type formed on the first base layer, wherein
the second base layer is formed on both lateral sides of the contact layer, and
the barrier layer is formed to be in contact with the second base layer that is formed on a first lateral side of the contact layer and the second base layer that is formed on a second lateral side of the contact layer that is opposite to the first lateral side.

5. The semiconductor device according to claim 1, further comprising:
a contact layer of the second conductivity type formed on the first base layer, wherein
the second base layer is formed on both lateral sides of the contact layer, and
the barrier layer is formed to be in contact with a first lateral side of the second base layer and not in contact with a second lateral side of the contact layer that is opposite to the first lateral side.

6. The semiconductor device according to claim 1, wherein
the maximum dopant concentration of the barrier layer is 5.0×10¹⁵ cm⁻³ to 1.5×10¹⁶ cm⁻³.

7. The semiconductor device according to claim 1, wherein
the maximum dopant concentration of the barrier layer is located at a depth within 0.5 micrometers from the first surface of the first base layer.

8. A semiconductor device comprising:
a first base layer of a first conductivity type formed on a semiconductor layer;
a second base layer of a second conductivity type formed on a first surface of the first base layer;
an emitter layer formed on the second base layer;
a collector layer of the second conductivity type formed above the first base layer;
a barrier layer of the first conductivity type, formed between the first base layer and the second base layer, the barrier layer having a depth from the first surface that is shallower than a depth of the second base layer from the first surface;
an insulating film formed on the second base layer; and
a gate electrode formed on the insulating film.

9. The semiconductor device according to claim 8, further comprising:
a buffer layer of the first conductivity type formed on the first base layer,
wherein the collector layer is formed on the buffer layer.

10. The semiconductor device according to claim 8, further comprising:
a contact layer of the second conductivity type formed on the first base layer, wherein
the second base layer is formed on both lateral sides of the contact layer, and
the barrier layer is formed to be in contact with the second base layer that is formed on a first lateral side of the contact layer and the second base layer that is formed on a second lateral side of the contact layer that is opposite to the first lateral side.

11. The semiconductor device according to claim 10, wherein the barrier layer has a dopant concentration that is higher than a dopant concentration of the first base layer and lower than a dopant concentration of the emitter layer.

12. The semiconductor device according to claim 8, further comprising:
a contact layer of the second conductivity type formed on the first base layer, wherein
the second base layer is formed on both lateral sides of the contact layer, and
the barrier layer is formed to be in contact with a first lateral side of the second base layer and not in contact with a second lateral side of the contact layer that is opposite to the first lateral side.

13. The semiconductor device according to claim 12, wherein the barrier layer has a dopant concentration that is higher than a dopant concentration of the first base layer and lower than a dopant concentration of the emitter layer.

14. The semiconductor device according to claim 8, wherein
the maximum dopant concentration of the barrier layer is 5.0×10¹⁵ cm⁻³ to 1.5×10¹⁶ cm⁻³.

15. The semiconductor device according to claim 8, wherein
the maximum dopant concentration of the barrier layer is located at a depth within 0.5 micrometers from the first surface of the first base layer.

16. A semiconductor device comprising:
a first base layer of a first conductivity type formed on a semiconductor layer;
a second base layer of a second conductivity type formed on a first surface of the first base layer;
an emitter layer formed on the second base layer;
a collector layer of the second conductivity type formed above the first base layer;
a barrier layer of the first conductivity type, formed between the first base layer and the second base layer, the barrier layer having a dopant concentration that is higher than a dopant concentration of the first base layer and lower than a dopant concentration of the emitter layer;
an insulating film formed on the second base layer; and
a gate electrode formed on the insulating film.

17. The semiconductor device according to claim 16, further comprising:
a buffer layer of the first conductivity type formed on the first base layer,
wherein the collector layer is formed on the buffer layer.

18. The semiconductor device according to claim 16, further comprising:
a contact layer of the second conductivity type formed on the first base layer, wherein
the second base layer is formed on both lateral sides of the contact layer, and
the barrier layer is formed to be in contact with the second base layer that is formed on a first lateral side of the contact layer and the second base layer that is formed on a second lateral side of the contact layer that is opposite to the first lateral side.

19. The semiconductor device according to claim 16, further comprising:
a contact layer of the second conductivity type formed on the first base layer, wherein
the second base layer is formed on both lateral sides of the contact layer, and
the barrier layer is formed to be in contact with a first lateral side of the second base layer and not in contact with a second lateral side of the contact layer that is opposite to the first lateral side.

20. The semiconductor device according to claim 16, wherein
the maximum dopant concentration of the barrier layer is 5.0×10¹⁵ cm⁻³ to 1.5×10¹⁶ cm⁻³ and is located at a depth within 0.5 micrometers from the first surface of the first base layer.
